(19) United States
(12) Patent Application Publication
(10) Pub. No.: US 2013/0263909 A1
(43) Pub. Date: Oct. 10, 2013

(54) SOLAR CELL MODULE

(71) Applicant: Sanyo Electric Co., Ltd., Osaka (JP)

(72) Inventors: Satoru OGASAHARA, Ichinomiya-shi (JP); Ryoji NAITO, Osaka (JP)

(21) Appl. No.: 13/907,774

(22) Filed: May 31, 2013

Related U.S. Application Data
(63) Continuation of application No. PCT/JP2012/005422, filed on Aug. 29, 2012.

(30) Foreign Application Priority Data
Aug. 30, 2011 (JP) 2011-187688
Dec. 28, 2011 (JP) 2011-289139

(51) Int. Cl. H01L 31/02

(52) U.S. Cl. CPC H01L 31/02013
USPC 136/244

(57) ABSTRACT

A solar cell module comprises: a translucent member arranged on the light reception side; a photovoltaic apparatus arranged on the translucent member; a wiring member configured to allow electric energy generated by the photovoltaic apparatus to be output to the exterior; a back face member having an opening configured to allow a lead wire to pass through it, and arranged such that it faces the translucent member; a shielding member arranged such that it overlays the through hole, and configured to shield the through hole; and a sealing member configured to seal the through hole. The lead wire is arranged so as to pass through a gap interposed between the shielding member and the back face member such that it bypasses the shielding member on the outlet side of the through hole. The sealing member is configured to seal the gap, in addition to sealing the through hole.

### CROSS-REFERENCE TO RELATED APPLICATIONS

This application is a Continuation of International Application No. PCT/JP2012/005422, filed on Aug. 29, 2012, which in turn claims the benefit of Japanese Application No. 2011-187688, filed on Aug. 30, 2011 and Japanese Patent Application No. 2011-289139, filed on Dec. 28, 2011, the disclosures of which applications are incorporated by reference herein.

### BACKGROUND OF THE INVENTION

1. Field of the Invention

The present invention relates to a solar cell module.

2. Description of the Related Art

As a conventional photoelectric conversion apparatus configured to convert light energy into electric energy, so-called solar cells are being intensively developed in many fields. Such solar cells are capable of directly converting light from the sun, which is a clean and inexhaustible energy source, into electric energy, and they are thus anticipated to become a new energy source.

For example, such a solar cell panel is provided as follows. That is to say, a transparent glass substrate, a filler adhesive agent layer, a photoelectric conversion panel, another filler adhesive agent layer, and a back face protection cover member are sequentially laminated so as to provide a monolithically integrated layered structure, following which the edge portion of the layered structure thus formed is sealed with a sealant. With such an arrangement, in order to allow the electric power generated in the photoelectric conversion panel to be output, a pair of leads connected to the photoelectric conversion panel are extended from the photoelectric conversion panel via the filler adhesive agent layer and the back face protection cover member, and are arranged in a box on the outer side of the back face protection cover member. A terminal opening is formed in the back face protection cover member so as to allow the pair of leads to pass through the back face protection cover member. With such an arrangement, in order to provide waterproofing, such a terminal opening is sealed with a filler adhesive agent such as silicone resin or the like.

### SUMMARY OF THE INVENTION

In order to allow such solar cells to be widely disseminated, the levelized cost must be reduced. In order to reduce the levelized cost, it is effective for such a photoelectric conversion apparatus to be configured to have a long service life. In some cases, water infiltrates the photoelectric conversion panel, which is a primary factor preventing such a photoelectric conversion apparatus from having a long service life. In order to protect the photoelectric conversion panel from water infiltration, the edge portion of the photoelectric conversion panel is sealed with a sealant, and the terminal opening is sealed with a filler adhesive agent, as described above.

However, after long-term use, such a sealant and such a filler adhesive agent deteriorate, leading to difficulty in preventing water infiltration. In particular, the terminal opening is arranged in the vicinity of the photoelectric conversion panel. Accordingly, water infiltration via the terminal opening leads to an increased risk of the occurrence of damage in the photoelectric conversion panel. The aforementioned filler adhesive agent is configured giving consideration to its waterproofing performance. However, there is room for improvement from the viewpoint of moisture proofing performance.

The present invention has been made in view of such a situation. Accordingly, it is a general purpose of the present invention to provide a technique for providing a solar cell module with a long service life.

In order to solve the aforementioned problem, a solar cell module according to an embodiment of the present invention comprises: a translucent member arranged on a light reception side; a photovoltaic apparatus arranged on the translucent member; a wire configured to allow electric energy generated by the photovoltaic apparatus to be output to the exterior; a back face member having an opening configured to allow a part of the wire to pass through it, and arranged such that it faces the translucent member; a shielding member arranged such that it overlays the opening as viewed along a direction that is orthogonal to the surface of the back face member, and configured to shield the opening; and a sealing member configured to seal the opening. The wire is arranged so as to pass through a gap interposed between the shielding member and the back face member such that it bypasses the shielding member on the outlet side of the opening. The sealing member is configured to seal the gap, in addition to sealing the opening.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a top view of a solar cell module according to the present embodiment a as viewed from the opposite side of the sunlight reception face;

FIG. 2 is a cross-sectional view of the solar cell module taken along line A-A in FIG. 1;

FIG. 3 is a cross-sectional view of a photovoltaic element taken along line B-B in FIG. 1;

FIG. 4 is an enlarged view of an internal structure of a terminal box shown in FIG. 2;

FIGS. 5A through 5C are schematic diagrams for describing a process according to a solar cell module manufacturing method according to the present embodiment;

FIGS. 6A through 6C are schematic diagrams for describing a process according to a solar cell module manufacturing method according to the present embodiment;

FIG. 7 is a schematic diagram for describing a manufacturing process for fusing and bonding a terminal to a wiring member;

FIG. 8 is an enlarged view of an internal structure of a terminal box of a solar cell module according to a modification of the first embodiment;

FIG. 9 is an enlarged view of an internal structure of a terminal box of a solar cell module according to another modification of the first embodiment;

FIG. 10 is an enlarged view of principal components of a solar cell module according to a second embodiment;

FIG. 11 is an enlarged view of principal components of a solar cell module according to a third modification, in the vicinity of the through hole and as viewed from the back face member side;

FIG. 12 is a cross-sectional view taken along line C-C in FIG. 11;

FIG. 13 is a cross-sectional view taken along line D-D in FIG. 11;

FIG. 14 is a diagram showing a modification of the solar cell module according to the third embodiment;

FIG. 15 is a diagram for describing a position relation between a sealing member and a shielding member in the internal structure of the terminal box; and

FIG. 16 is a diagram for describing a position relation between a sealing member and a shielding member in the internal structure of the terminal box.

### DETAILED DESCRIPTION OF THE INVENTION

The invention will now be described by reference to the preferred embodiments. This does not intend to limit the scope of the present invention, but to exemplify the invention.

Detailed description will be made with reference to the drawings regarding embodiments configured to provide the present invention. It should be noted that, in description with reference to the drawings, the same components are denoted by the same reference symbols, and redundant description thereof will be omitted as appropriate.

The scale and the form of each layer and each portion in the drawings are determined for convenience for ease of description, and are by no means intended to be restricted in particular in the absence of explicit definition.

### First Embodiment

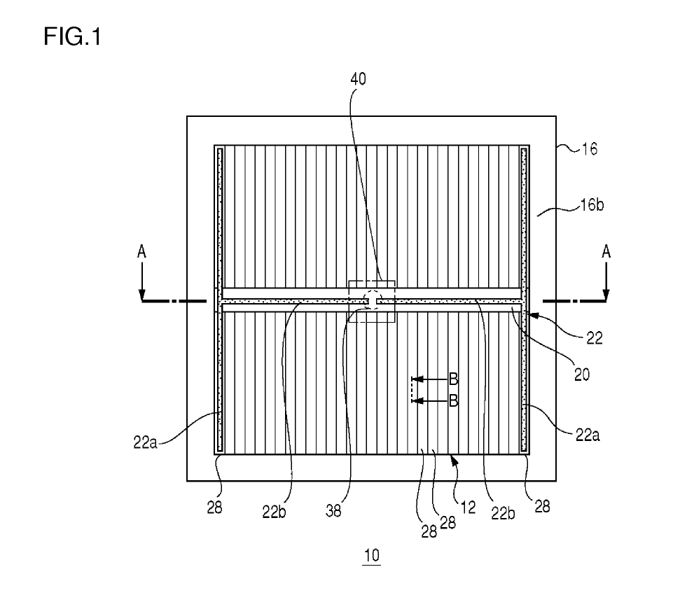

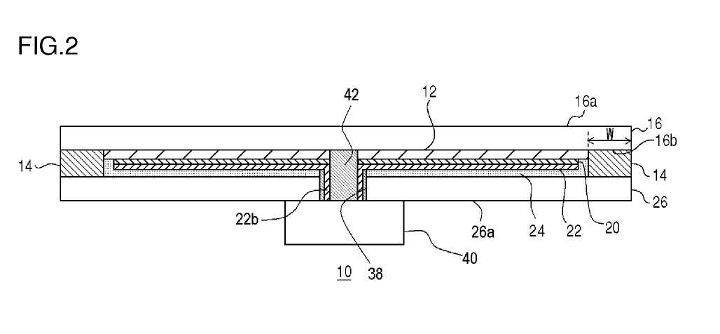

FIG. 1 is a top view of a solar cell module according to the present embodiment as viewed from the opposite side of the sunlight reception face. FIG. 2 is a cross-sectional view of the solar cell module taken along the line A-A in FIG. 1. It should be noted that, in FIG. 1, a sealing member, a filler member, and a back face member, and the like, are not shown.

A solar cell module 10 includes a photovoltaic apparatus 12, a sealing member 14, a translucent member 16, an insulating member 20, a wiring member 22, a filler member 24, and a back face member 26 configured as a protection member.

The photovoltaic apparatus 12 is configured as a rectangular flat plate or film-shaped unit, and has a configuration in which multiple photovoltaic elements 28 are aligned. The photovoltaic elements 28 are connected to each other in series or otherwise in parallel as appropriate.

The translucent member 16 is formed of a material through which light can be transmitted. The multiple photovoltaic elements 28 are formed as the photovoltaic apparatus 12 on the back face 16b of the translucent member 16, which is the opposite side of the light reception face 16a.

As described above, as viewed from directly in front of the light reception face 16a, the translucent member 16 is arranged such that it covers the photovoltaic apparatus 12. It should be noted that the translucent member 16 may be configured as a glass member, a plastic member, or the like, having a high resistivity. In particular, the translucent member 16 is preferably formed of a material having high transmittance with respect to the wavelengths of sunlight.

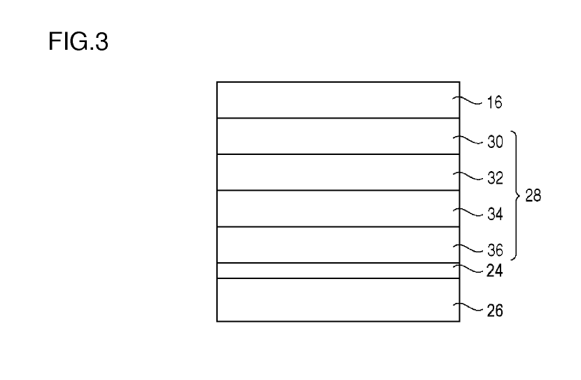

Next, description will be made regarding the photovoltaic element 28. FIG. 3 is a cross-sectional view of the photovoltaic element taken along the line B-B in FIG. 1. The photovoltaic element 28 includes a first electrode layer 30, a semiconductor layer 32, a transparent conductive film 34, and a second electrode layer 36. The first electrode layer 30, the semiconductor layer 32, the transparent conductive film 34, and the second electrode layer 36 are sequentially laminated on the translucent member 16 in this order, and are respectively patterned using known laser patterning techniques. Furthermore, the filler member 24 and the back face member 26 are laminated on the second electrode layer 36.

The first electrode layer 30 is formed on the face of the translucent member 16, and is configured to have electrical conductivity and translucency. As the first electrode layer 30 according to the present embodiment, a transparent conductive oxide (TCO) layer is employed. In particular, zinc oxide (ZnO), which provides advantages of high transmissivity, low resistance, and low cost, is employed.

The semiconductor layer 32 allows a charge pair (electron and hole) to be generated using the incident light received via the first electrode layer 30 side. As the semiconductor layer 32, such an arrangement may employ a single layer body or otherwise a laminated layer body formed of an amorphous (non-crystalline) silicon semiconductor layer, microcrystalline silicon semiconductor layer, or the like, having a pin junction or pn junction as a basic structure. The semiconductor layer 32 according to the present embodiment has a structure in which an amorphous silicon semiconductor layer and a microcrystalline silicon semiconductor layer are laminated from the first electrode layer 30 side. It should be noted that, in the present specification, the term “microcrystalline” also means a state in which the crystalline layer is partially configured as an amorphous layer, in addition to a state in which the entire layer is configured as a crystalline layer.

The transparent conductive film 34 is formed on the semiconductor layer 32. The transparent conductive film 34 prevents the semiconductor layer 32 and the second electrode layer 36 from forming an alloy, and provides reduced connection resistance between the semiconductor layer 32 and the second electrode layer 36.

The second electrode layer 36 is formed on the transparent conductive film 34. The second electrode layer 36 is formed of a reflective metal material such as silver (Ag) or the like. The transparent conductive film 34 and the second electrode layer 36 of each photovoltaic element 28 are arranged so as to be in contact with the first electrode layer 30 of the adjacent different photovoltaic element 28. Such a structure electrically connects in series each photovoltaic element 28 with a corresponding different photovoltaic element 28.

The wiring member 22 shown in FIG. 1 or 2 allows the charges generated by the multiple photovoltaic elements 28 thus connected in series to be output to the exterior of the solar cell module 10. The wiring member 22 includes a conductive portion 22a electrically conductively connected to a pair of photovoltaic elements 28 arranged on the respective ends of an array of the multiple photovoltaic elements 28 connected in series. The wiring member 22 is preferably configured of a material such as copper (Cu) or the like having low resistivity, partially coated with solder. It should be noted that the insulating member 20 is arranged at a predetermined region between the wiring member 22 and an array of the multiple photovoltaic elements 28. Such a structure partially insulates the multiple photovoltaic elements 28 from a lead wire 22b of the wiring member 22.

The photovoltaic apparatus 12 and the wiring member 22 are sealed by the filler member 24 between the translucent member 16 and the back face member 26 so as to absorb impact inflicted on the photovoltaic elements 28. With the present embodiment, the filler member 24 is formed of ethylene vinyl acetate (EVA). Furthermore, with the present embodiment, the back face member 26 is formed of low-cost blue sheet glass (float glass). It should be noted that such a blue sheet glass member contains alkali metal such as sodium (Na) and the like as impurity ions. The back face member 26 provides a function of improving the overall strength of the solar cell module 10 and a function of protecting the solar cell module 10 from infiltration of water or impurities from the back face side.

The sealing member 14 is arranged so as to be attached to the outer side of the filler member 24 arranged between the translucent member 16 and the back face member 26, thereby sealing the panel edge portion. The sealing member 14 is preferably formed of a resin such as a butyl rubber or the like having a low moisture vapor transmission rate.

In particular, in a case in which the sealing member 14 is formed of a butyl rubber, the sealing member 14 is formed with a width W (see FIG. 2) of 10 mm or more, for example. It is known that such an arrangement comprising the sealing member 14 having a width W of 10 mm or more provides an effect of protecting the solar cell module 10 from moisture vapor infiltration from the edge portion over a long period of time on the order of three times the test time (1000 hours) stipulated as the high-temperature and high-pressure test time (85° C., 85% RH).

With the solar cell module 10, as the width W of the sealing member 14 of the completed solar cell module 10 becomes wider, the moisture vapor barrier effect becomes higher. However, such an arrangement has a disadvantage of a reduced effective area used for electric power generation by the solar cell module 10. Thus, in a case of employing a butyl rubber material or a sealing member having similar properties, the sealing member 14 is preferably configured to have a width W ranging between 10 and 15 mm. It should be noted that, in a case in which high priority is assigned to the moisture vapor barrier effect, the sealing member 14 may be configured with a width of 15 mm or more.

In contrast, in a case in which high priority is assigned to the power generation efficiency of the solar cell module 10, and in a case in which there is little damage to the solar cell module 10 if water infiltrates the solar cell module 10, the sealing member 14 may be configured with a width of 10 mm or less.

A through hole 38, which is an opening, is formed in the filler member 24 and the back face member 26. One terminal of the lead wire 22b of the wiring member 22 is connected to a terminal box 40 such that it passes through the filler member 24 and the back face member 26. The through hole 38 is sealed with the sealing member 42 in a state in which the lead wire 22b passes through the through hole 38. Description will be made later regarding the internal structure of the terminal box 40.

As described above, the solar cell module 10 according to the first embodiment includes: the translucent member 16 arranged on the light reception side; the photovoltaic apparatus 12 arranged on the translucent member 16; the wiring member 22 which allows electric energy generated by the photovoltaic apparatus to be output to the exterior; the back face member 26 arranged such that it faces the translucent member 16 and including the through hole 38 formed so as to allow the lead wire 22b, which is a part of the wiring member 22, to pass through the back face member 26; and the sealing member 42 configured to seal the through hole 38.

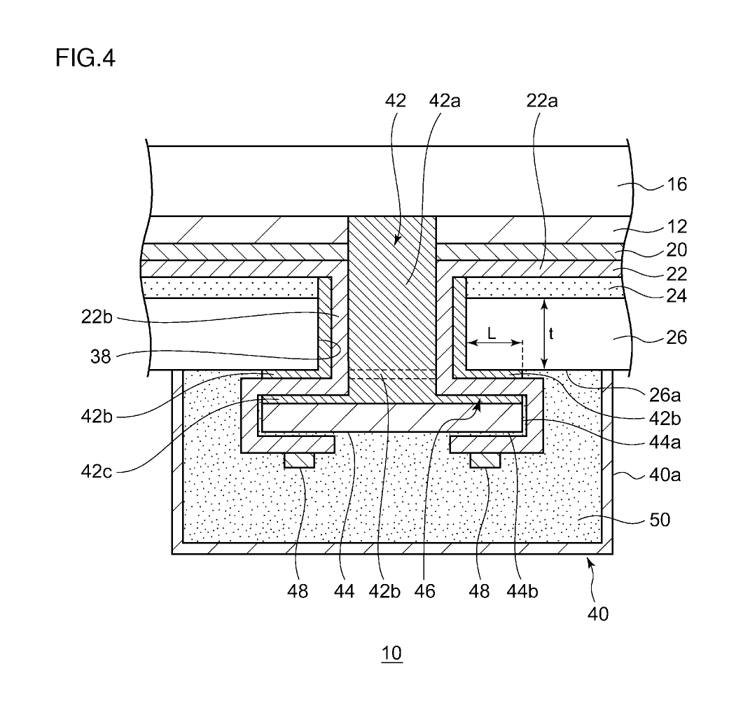

FIG. 4 is an enlarged view of the internal structure of the terminal box shown in FIG. 2. The solar cell module 10 includes a shielding member 44. The shielding member 44 is arranged such that it overlays the through hole 38 as viewed along the direction that is orthogonal to the surface of the back face member 26, thereby shielding the through hole 38. The lead wire 22b is arranged such that it bypasses the shielding member 44 on the outlet side of the through hole 38 and such that it passes through a gap region 46 between the shielding member 44 and the back face member 26. The sealing member 42 seals the gap region 46, in addition to sealing the through hole 38. It should be noted that the sealing member 42 mainly comprises: a hole sealing portion 42a configured to seal the through hole 38; a first gap sealing portion 42b configured to seal the gap between the back face member 26 and the lead wire 22b; and a second gap sealing portion 42c configured to seal the gap between the lead wire 22b and the shielding member 44.

More specifically, the lead wire 22b is arranged such that it is bent approximately 90 degrees on the outlet side of the through hole 38 and extends toward the outer side along the surface 26a of the back face member 26. Furthermore, the lead wire 22b is again bent approximately 90 degrees after it crosses the edge 44a of the shielding member 44, and is arranged such that it extends toward the side opposite to the back face member 26 along the edge 44a of the shielding member 44. Moreover, the lead wire 22b is again bent approximately 90 degrees on the surface 44b of the shielding member 44. The terminal of the lead wire 22b is connected to an output terminal 48 in this state.

With such an arrangement, assuming that moisture vapor in the exterior air cannot directly infiltrate the shielding member 44, the moisture vapor must pass through the gap region 46 such that it bypasses the shielding member 44 in order to reach the through hole 38. Thus, the solar cell module 10 according to the present embodiment lengthens the distance which moisture vapor must pass through before it reaches the photovoltaic apparatus 12 through the sealing member 42, as compared with an arrangement including no shielding member 44. Thus, such an arrangement is capable of suppressing the amount of moisture vapor that can reach the photovoltaic apparatus 12 via the sealing member 42. As a result, such an arrangement suppresses deterioration in the photovoltaic apparatus 12 and the wiring member 22 itself, and suppresses degradation of the connection reliability of the respective connection portions that connect the respective components and wires, over a long period of time, thereby providing the solar cell module with a long service life.

It should be noted that the shielding member 44 is formed of glass. Thus, such an arrangement allows the amount of moisture vapor that directly passes through the shielding member 44 to be reduced. Furthermore, the sealing member 42 is formed of a butyl rubber. Thus, such an arrangement allows the amount of moisture vapor that can reach the internal structure of the solar cell module 10 via the sealing member 42 to be further reduced.

It should be noted that, with the present embodiment, in a case in which the sealing member 42 is formed of a material that is equivalent to that of the sealing member 14, as shown in FIG. 2 or 4, with the thickness of the back face member 26 as t [mm], with the length of the gap region 46 from the edge of the outlet side of the through hole 38 up to the edge 44a which is the outer edge of the shielding member 44 as L [mm], and with the width of the sealing member 14 arranged at the edge portion of the solar cell module 10 as W [mm], the shapes and sizes of the various components are determined so as to satisfy the condition t+L≧W. It should be noted that, in a case in which the length of the gap region 46 is not constant, the smallest length of the gap region 46 is used as L.

If the value obtained by (the thickness t+the length L) is approximately the same as the width W of the sealing member 14, the barrier performance of the sealing member 42 with respect to moisture vapor is approximately the same as the barrier performance of the edge portion of the solar cell module 10 with respect to moisture vapor. Furthermore, such an arrangement requires only a minimum shielding member to be used, thereby reducing the manufacturing cost.

In particular, in a case in which the sealing member 42 and the sealing member 14 are formed of a material such as a butyl rubber, such an arrangement may preferably be designed so as to satisfy the condition t+L≧10 mm. It is known that such an arrangement configured to satisfy the condition t+L≧10 mm provides a moisture vapor infiltration protection effect over a long period of time on the order of three times the test time (1000 hours) stipulated as the high-temperature and high-pressure test time (85° C., 85% RH).

As the (t+L) value of the completed solar cell module 10 becomes greater, the moisture vapor barrier effect becomes higher. However, such an arrangement with a large (t+L) value has a problem of the shielding member 44 having a large size, and a problem of an increase in the quantity of the sealing member 42 or tab wiring to be arranged. Accordingly, in a case in which the (t+L) value is designed to be equal to or greater than the width W of the sealing member 14, and in a case in which the sealing member is formed of a butyl rubber material or a material having approximately the same performance level, the (t+L) value is preferably designed in a range between 10 and 15 mm. It should be noted that, in a case in which a high priority is assigned to the moisture vapor barrier effect, the sealing member 14 may be formed with a width W of 15 mm or more.

In contrast, in a case in which a high priority is assigned to the power generation efficiency of the solar cell module 10, in a case in which there is little damage to the solar cell module 10 if water infiltrates the solar cell module 10, or in a case in which the sealing member 14 is formed of a material having a barrier performance that is higher than the sealing member formed of a butyl rubber, the sealing member 14 may be configured with a width W that is smaller than 10 mm, and the (t+L) value may be designed to be smaller than 10 mm according to the width W.

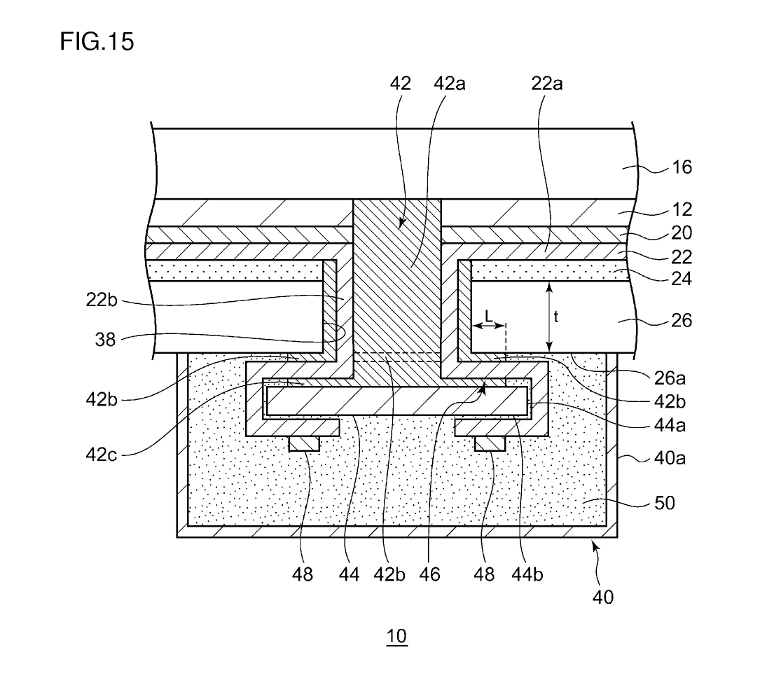

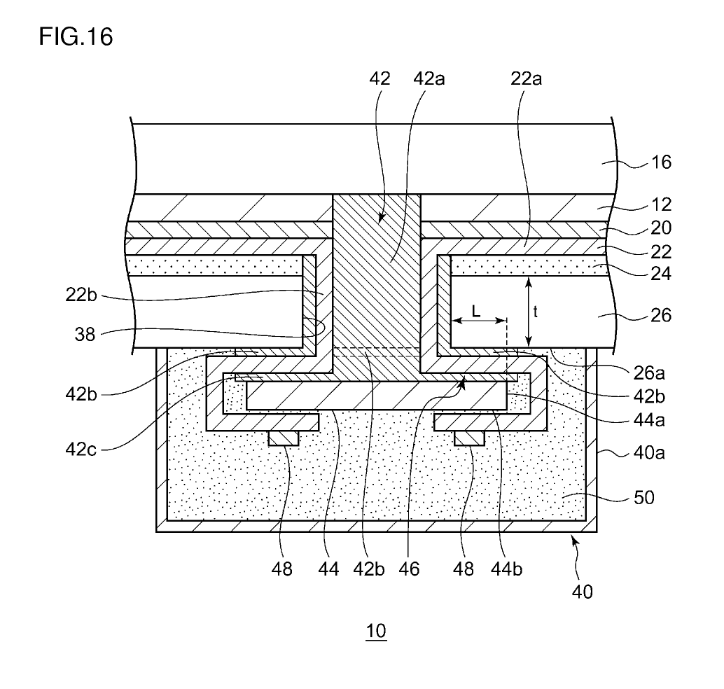

It should be noted that the position relation between the sealing member 42 and the shielding member 44 is not restricted to an arrangement shown in FIG. 4. FIGS. 15 and 16 are diagrams each showing the position relation between the sealing member 42 and the shielding member 44 within the terminal box.

FIG. 15 shows an arrangement having a position relation between the sealing member 42 and the shielding member 44 in which the sealing member 42 is provided such that the edge portion 44a of the shielding member 44 has not been filled with the sealing member 42. Such an arrangement with the sealing member 42 in such a state shown in FIG. 15 provides the same effects as in the state of the sealing member 42 shown in FIG. 4, as long as the (t+L) value is within the aforementioned range.

In contrast, FIG. 16 shows an arrangement having a position relation between the sealing member 42 and the shielding member 44 in which the sealing member 42 is provided such that it protrudes from the edge portion 44a of the shielding member 44. Such an arrangement with the sealing member 42 in such a state shown in FIG. 16 provides the same effects as in the state of the sealing member 42 shown in FIG. 4, as long as the (t+L) value is within the aforementioned range.

It should be noted that the terminal box 40 includes a housing portion 40a configured to house the shielding member 44 and a filler member 50 configured to fill the interior space of the housing portion 40a. The filler member 50 is formed of a material having a heat radiation performance that is higher than that of the sealing member 42. For example, the filler member 50 is formed of a silicone or the like. Such an arrangement allows heat generated in the internal components and circuits arranged within the terminal box 40 to be easily radiated to the exterior via the filler member 50.

### [Manufacturing Method for a Solar Cell Module]

Next, description will be made regarding a manufacturing method for a solar cell module including the aforementioned solar cells. Description will made below regarding a solar cell module including multiple photovoltaic elements 28. Also, the solar cell module may be configured to have a single photovoltaic element 28.

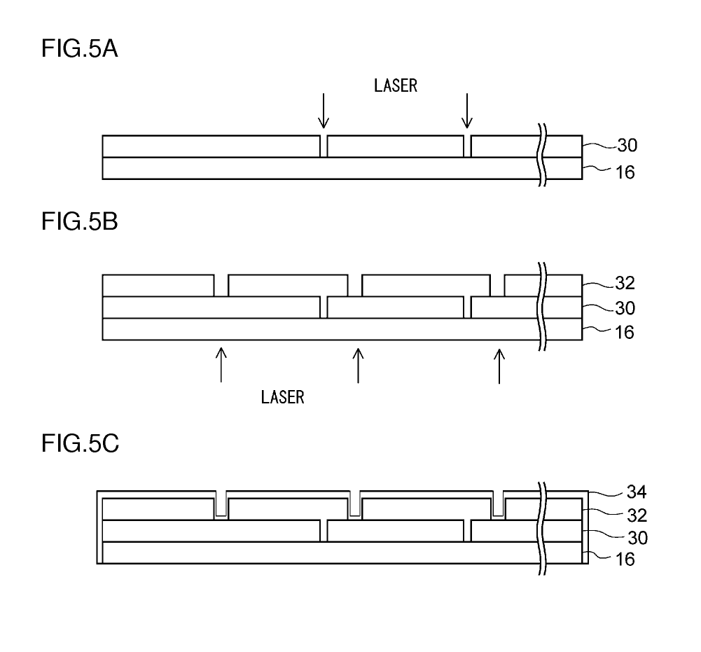

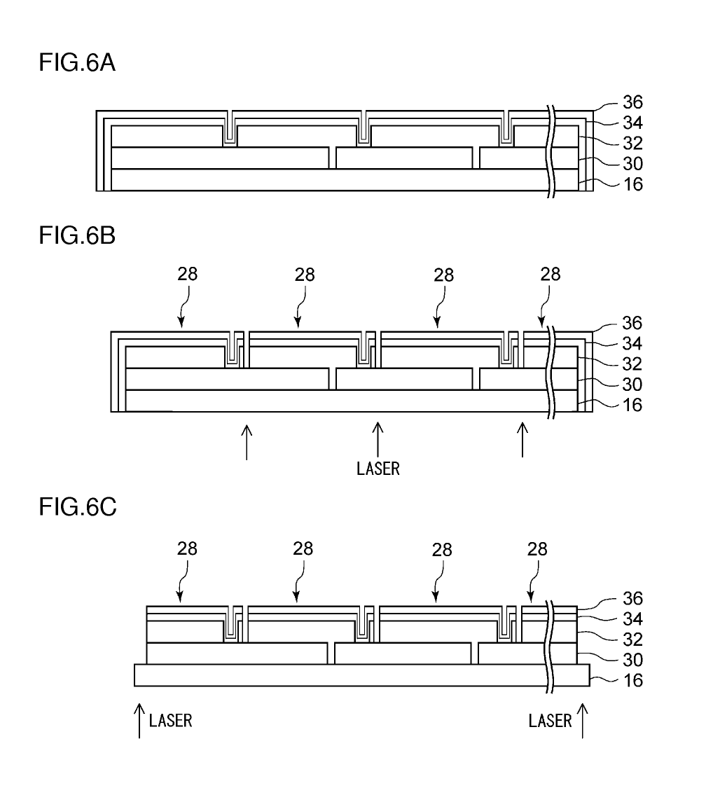

FIGS. 5 and 6 are schematic diagrams each showing manufacturing stages of a manufacturing method for a solar cell module according to the present embodiment.

First, as shown in FIG. 5A, the first electrode layer 30 is formed by means of sputtering of zinc oxide (ZnO) with a thickness of 600 nm on a translucent member 16 formed of a glass substrate having a thickness of 4 mm. Next, the first electrode layer 30 is irradiated with YAG laser light from the first electrode layer 30 side of the translucent member 16, and is thus patterned into multiple strip-shaped regions.

Next, as shown in FIG. 5B, the semiconductor layer 32 is formed by means of a plasma processing apparatus (plasma CVD). The semiconductor layer 32 is obtained by sequentially laminating, on the first electrode layer 30, a p-type amorphous silicon semiconductor film having a thickness of 15 nm, an i-type amorphous silicon semiconductor film having a thickness of 200 nm, an n-type amorphous silicon semiconductor film having a thickness of 30 nm, a p-type microcrystalline silicon semiconductor film having a thickness of 30 nm, an i-type microcrystalline silicon semiconductor film having a thickness of 2000 nm, and an n-type microcrystalline silicon semiconductor film having a thickness of 30 nm.

The p-type amorphous silicon semiconductor film is formed using a mixture of silane (SiH₄), methane (CH₄), hydrogen (H₂), and diborane (B₂H₆) as a gas material. The i-type amorphous silicon semiconductor film is formed using a mixture of silane (SiH₄) and hydrogen (H₂) as a gas material. The n-type amorphous silicon semiconductor film is formed using a mixture of silane (SiH₄), hydrogen (H₂), and phosphine (PH₃) as a gas material.

The p-type microcrystalline silicon semiconductor film is formed using a mixture of silane (SiH₄), hydrogen (H₂), and diborane (B₂H₆) as a gas material. The i-type microcrystalline silicon semiconductor film is formed using a mixture of silane (SiH₄) and hydrogen (H₂) as a gas material. The n-type microcrystalline silicon semiconductor film is formed using a mixture of silane (SiH₄), hydrogen (H₂), and phosphine (PH₃) as a gas material.

| | | SUBSTRATE | | REACTION | | FILM |
|---|---|---|---|---|---|---|
| | LAYER | TEMPERATURE | GAS FLOW | PRESSURE | | THICKNESS |
| | (FILM) | (° C.) | (sccm) | (Pa) | RF POWER (W) | (nm) |
| AMORPHOUS | p-TYPE | 180 | SiH₄: 300 | 106 | 10 | 15 |
| SILICON | LAYER | | CH₄: 300 | | | |
| SEMICONDUCTOR | | | H₂: 2000 | | | |
| LAYER | | | B₂H₆: 3 | | | |
| | i-TYPE | 200 | SiH₄: 300 | 106 | 20 | 200 |
| | LAYER | | H₂: 2000 | | | |
| | n-TYPE | 200 | SiH₄: 300 | 133 | 20 | 30 |
| | LAYER | | H₂: 2000 | | | |
| | | | PH₃: 5 | | | |
| MICROCRYSTALLINE | p-TYPE | 180 | SiH₄: 10 | 106 | 10 | 30 |
| SILICON | LAYER | | H₂: 2000 | | | |
| SEMICONDUCTOR | | | B₂H₆: 3 | | | |
| LAYER | i-TYPE | 200 | SiH₄: 100 | 133 | 20 | 2000 |
| | LAYER | | H₂: 2000 | | | |
| | n-TYPE | 200 | SiH₄: 10 | 133 | 20 | 30 |
| | LAYER | | H₂: 2000 | | | |
| | | | PH₃: 5 | | | |

shows detailed film formation conditions for the respective films provided by the plasma processing apparatus.

### [Table 1]

| | | SUBSTRATE | | REACTION | | FILM |
|---|---|---|---|---|---|---|
| | LAYER | TEMPERATURE | GAS FLOW | PRESSURE | | THICKNESS |
| | (FILM) | (° C.) | (sccm) | (Pa) | RF POWER (W) | (nm) |
| AMORPHOUS | p-TYPE | 180 | SiH₄: 300 | 106 | 10 | 15 |
| SILICON | LAYER | | CH₄: 300 | | | |
| SEMICONDUCTOR | | | H₂: 2000 | | | |
| LAYER | | | B₂H₆: 3 | | | |
| | i-TYPE | 200 | SiH₄: 300 | 106 | 20 | 200 |
| | LAYER | | H₂: 2000 | | | |
| | n-TYPE | 200 | SiH₄: 300 | 133 | 20 | 30 |
| | LAYER | | H₂: 2000 | | | |
| | | | PH₃: 5 | | | |
| MICROCRYSTALLINE | p-TYPE | 180 | SiH₄: 10 | 106 | 10 | 30 |
| SILICON | LAYER | | H₂: 2000 | | | |
| SEMICONDUCTOR | | | B₂H₆: 3 | | | |
| LAYER | i-TYPE | 200 | SiH₄: 100 | 133 | 20 | 2000 |
| | LAYER | | H₂: 2000 | | | |
| | n-TYPE | 200 | SiH₄: 10 | 133 | 20 | 30 |
| | LAYER | | H₂: 2000 | | | |
| | | | PH₃: 5 | | | |

By irradiating respective positions, which are offset with respect to the patterned positions of the first electrode layer 30, with YAG laser light from the surface side (translucent member 16 side), a part of the semiconductor layer 32 formed on the back face side of the translucent member 16 is removed so as to form multiple isolated regions, thereby patterning the semiconductor layer 32 into multiple strip-shaped regions.

Next, as shown in FIG. 5C, the transparent conductive film 34 is formed of zinc oxide (ZnO) on the semiconductor layer 32 by means of sputtering. The transparent conductive film 34 is also formed at the regions where the semiconductor layer 32 has been removed by means of patterning and at the side edge portions.

Next, as shown in FIG. 6A, a silver (Ag) film having a thickness of 200 nm is formed on the transparent conductive film 34 by means of sputtering, thereby forming a second electrode layer 36. In this step, the second electrode layer 36 is also formed on the transparent conductive film 34 in the regions where the semiconductor layer 32 has been removed by means of patterning.

Next, as shown in FIG. 6B, the respective positions which are offset with respect to the patterned positions of the semiconductor layer 32 are irradiated with YAG laser light from the surface side (translucent member 16 side), so as to form isolated regions each of which is formed of the semiconductor layer 32, the transparent conductive film 34, and the second electrode layer 36, thereby obtaining strip-shaped patterned regions.

Next, as shown in FIG. 6C, the transparent conductive film 34 and the second electrode layer 36 that extend over the edge portion (outermost edge portions) of the first electrode layer 30 and the edge portion of the semiconductor layer 32 are removed by means of laser irradiation from the surface side.

By executing the aforementioned steps, multiple photovoltaic elements 28 are formed on the translucent member 16 such that they are connected to each other in series.

Next, the translucent member 16 having one face on which the photovoltaic apparatus 12 is formed is prepared. Furthermore, the wiring member 22 is arranged on the photovoltaic apparatus 12 such that the lead wire 22b is stood upright.

Next, the sheet-shaped filler member 24 formed of ethylene vinyl acetate (EVA) configured to coat the photovoltaic apparatus 12, the back face member 26, the sealing member 14, and the hole sealing portion 42a are arranged on the photovoltaic apparatus 12. Subsequently, a filler member or a sealing member is fused by means of a vacuum laminating apparatus or the like, in a state in which one terminal of the lead wire 22b is arranged such that it has been drawn out to the exterior, thereby filling the interior space of the module. Thus, the translucent member 16 is adhered to the back face member 26, and the through hole 38 is sealed. The sealing member 14 is configured to have a width of 10 to 15 mm after the solar cell module is completed.

Subsequently, the shielding member 44 is arranged so as to shield the through hole 38. Next, as shown in FIG. 4, the lead wire 22b is bent after it is drawn out such that it bypasses the shielding member 44. In this step, the sealing members (the first gap sealing portion 42b and the second gap sealing portion 42c) are arranged between the surface 26a of the back face member 26 and the shielding member 44 such that the lead wire 22b is interposed between them, thereby adhering these components to each other.

It should be noted that, in a case in which the hole sealing portion 42a, the first gap sealing portion 42b, and the second gap sealing portion 42c are each formed of the same material (e.g., a butyl rubber material) in the aforementioned steps, the laminating processing can be performed after the respective portions that form the sealing member 42 are all arranged, thereby allowing the number of manufacturing steps to be reduced.

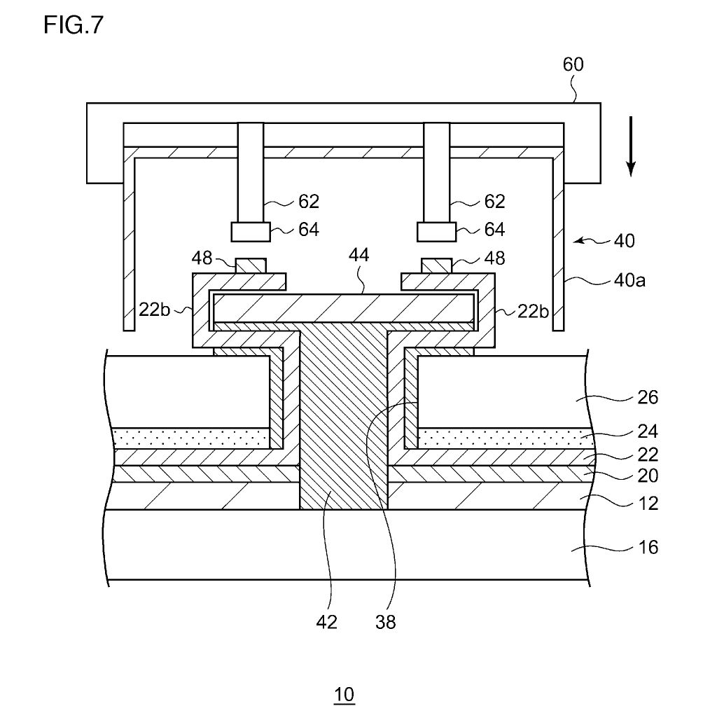

FIG. 7 is a schematic diagram for describing a step for fusing the terminal to the wiring. A jig 60 shown in FIG. 7 is configured to hold the housing portion 40a of the terminal box 40, and includes soldering irons 62. Each soldering iron 62 includes, at its tip, a terminal gripping/heating base 64 configured to heat the output terminal 48 while gripping the output terminal 48.

In this step, the output terminal 48 is mounted on the lead wire 22b arranged on the shielding member 44. In this state, the jig 60 is lowered, and the output terminal 48 is gripped and heated by means of the terminal gripping/heating base 64. In this manner, the lead wire 22b is connected, via solder on the shielding member 44, to the output terminal 48. With such an arrangement, the shielding member 44 is formed of glass, which is an insulating material. Thus, such an arrangement allows the lead wire 22b to be connected to the output terminal 48 using the shielding member 44 as a base. Thus, such an arrangement allows the jig 60 to automatically connect the lead wire 22b to the output terminal 48, thereby facilitating mass production.

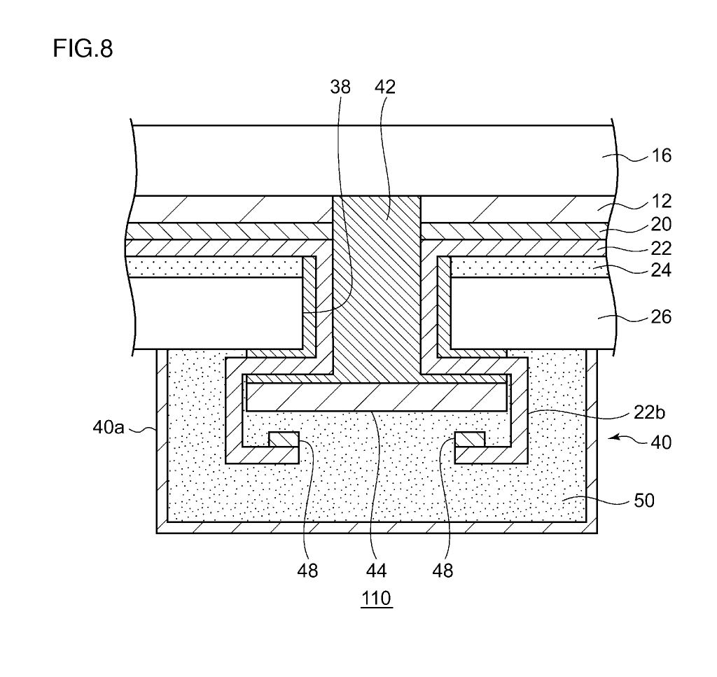

FIG. 8 is an enlarged view of the internal structure of the terminal box of the solar cell module according to a modification of the first embodiment.

With a solar cell module 110, a lead wire 22b is connected to the output terminal 48 via solder with a gap between it and the shielding member 44. Such a structure suppresses the transfer of heat via the shielding member 44 when heat is generated in the step in which the lead wire 22b is connected to the output terminal 48 by means of soldering. Thus, such an arrangement suppresses alteration of the sealing member 42 and degradation of the photovoltaic apparatus 12 due to heat.

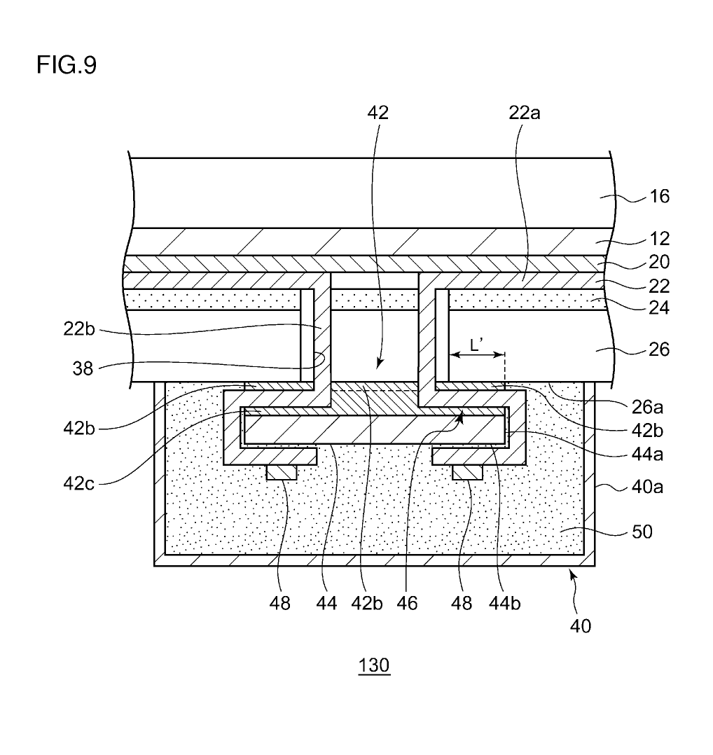

FIG. 9 is an enlarged view of an internal structure of a terminal box of a solar cell module according another modification of the first embodiment.

A solar cell module 130 shown in FIG. 9 has a structure in which the interior space of the through hole 38 is not filled with the sealing member 42, and which is sealed by the first gap sealing portion 42b and the second gap sealing portion 42c. With such an arrangement, with the length of the gap region 46 as L′, the shapes and sizes of the various components are determined so as to satisfy the condition L′≧10 mm. More preferably, the respective components may be designed so as to satisfy the condition L′≧15 mm. By increasing the distance of permeation of moisture vapor, such an arrangement is capable of further reducing the amount of moisture vapor that reaches the internal structure of the solar cell module 130 via the sealing member 42.

In the manufacturing of the solar cell module 130, in the step in which the sheet-shaped filler member 24 is arranged, the aforementioned hole sealing portion 42a is not arranged, as described above. Next, in the step in which the shielding member 44 is arranged, all the sealing members (first gap sealing portion 42b and second gap sealing portion 42c) are arranged such that the lead wire 22b is interposed between the surface 26a of the back face member 26 and the shielding member 44. Subsequently, the laminating processing is performed, as described above.

### Second Embodiment

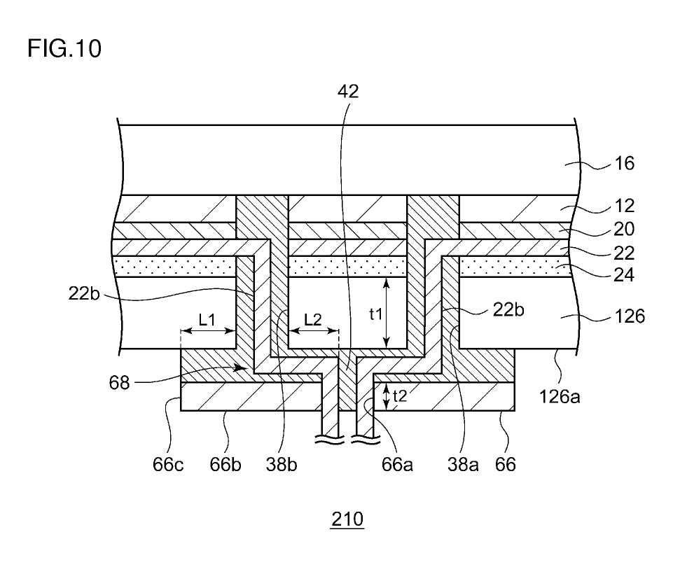

FIG. 10 is an enlarged view of the principal components of a solar cell module according to a second embodiment.

A solar cell module 210 has a structure in which two through holes are formed in the back face member and a single through hole is further formed in the central portion of the shielding member, which is the major difference between it and the solar cell module 10 according to the first embodiment. It should be noted that the same components as those in the first embodiment are denoted by the same reference numerals, and description will be omitted as appropriate.

With the present embodiment, two through holes 38a and 38b are formed in the back face member 126. Each through hole is sealed with the sealing member 42 with the corresponding one of the two lead wires 22b passing through it.

The solar cell module 210 includes a shielding member 66. The shielding member 66 is arranged such that it overlays the through holes 38a and 38b as viewed along the direction that is orthogonal to the surface of the back face member 126, thereby shielding the through holes 38a and 38b. The shielding member 66 is configured as a glass plate having a through hole 66a formed in its central portion. The two lead wires 22b are arranged such that they pass through a gap region 68 between the shielding member 66 and the back face member 126 so as to bypass the shielding member 66 after they protrude from the respective outlet sides of the through holes 38a and 38b. Furthermore, the sealing member 42 seals the gap region 68, in addition to sealing the through holes 38a and 38b.

More specifically, each lead wire 22b is arranged such that it is bent approximately 90 degrees on the outlet side of the through hole 38a (38b) and extends toward the inner side along the surface 126a of the back face member 126. Furthermore, the lead wire 22b is again bent approximately 90 degrees after it crosses the outer edge of the through hole 66a formed in the shielding member 66, and is arranged such that it protrudes from the surface 66b of the shielding member 66 via the through hole 66a. The terminal of the lead wire 22b is connected to the output terminal 48.

With such an arrangement, assuming that moisture vapor in the exterior air cannot directly infiltrate the shielding member 66, the moisture vapor must pass through the gap region 68 such that it bypasses the shielding member 66 in order to reach the through hole 38a or 38b. Thus, the solar cell module 210 according to the present embodiment suppresses the amount of moisture vapor that can reach the photovoltaic apparatus 12 via the sealing member 42, as compared with an arrangement having no shielding member 66. As a result, such an arrangement suppresses deterioration in the photovoltaic apparatus 12 and the wiring member 22 itself, and suppresses degradation of the connection reliability of the respective connection portions that connect the respective components and wires, over a long period of time, thereby providing the solar cell module with a long service life.

It should be noted that, with the present embodiment, as shown in FIG. 10, with the thickness of the back face member 126 as t1, with the thickness of the shielding member 66 as t2, with the length of the gap region 68 that extends between the edge of the outlet of the through hole 38a (38b) and the edge portion 66c which is the outer edge of the shielding member 66 as L1, and with the length of the gap region 68 that extends between the edge of the outlet of the through hole 38a (38b) and the outer edge of the through hole 66a as L2, the shapes and sizes, and the layout, of the various components are determined so as to satisfy the condition t1+L1≧10 mm. More preferably, the shapes and sizes, and the layout, of the various components may be determined so as to satisfy the condition t1+L1≧15 mm. Furthermore, the shapes and sizes, and the layout, of the various components are determined so as to satisfy the condition t1+t2+L2≧10 mm. More preferably, the shapes and sizes, and the layout, of the various components are determined so as to satisfy the condition t1+t2+L2≧15 mm. As described above, by increasing the moisture vapor infiltration distance, such an arrangement is capable of further reducing the amount of moisture vapor that infiltrates the sealing member 42 and reaches the internal structure of the solar cell module 10.

As described above, the solar cell module according to the aforementioned embodiment includes the translucent member and the back face member, and has a structure in which the shielding member having a size that is greater than the size of the through hole is arranged such that it covers, via a butyl rubber, the through hole configured as a terminal through hole provided to the back face member. Furthermore, the lead wires are arranged along the gap region filled with a butyl rubber. Thus, by designing the size of the shielding member as appropriate with respect to the through hole, such an arrangement ensures a sufficient moisture vapor infiltration distance, thereby improving the sealing performance of the through hole with respect to moisture vapor.

### Third Embodiment

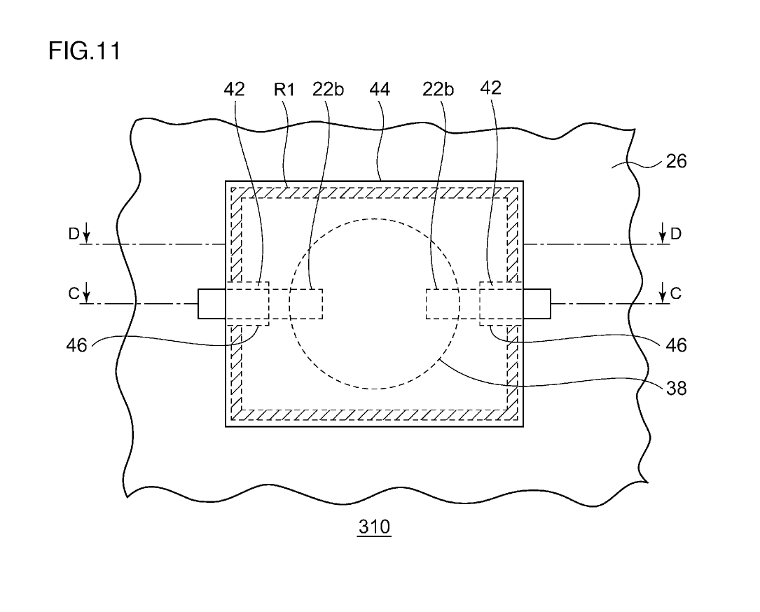

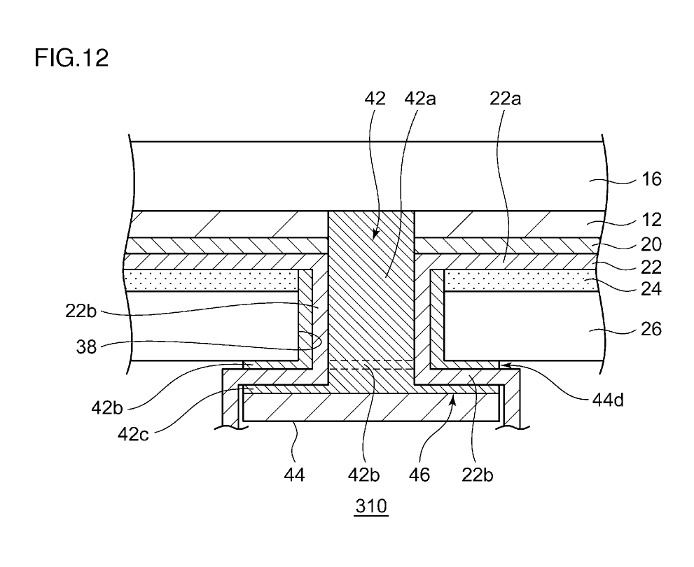

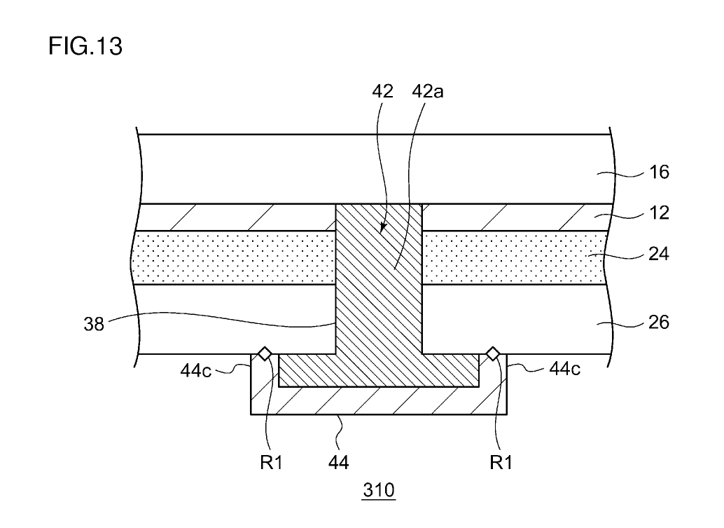

FIG. 11 is an enlarged view of principal components of a solar cell module according to a third embodiment, in the vicinity of the through hole as viewed from the back face member side. FIG. 12 is a cross-sectional view taken along the line C-C shown in FIG. 11. FIG. 13 is a cross-sectional view taken along the line D-D shown in FIG. 11. The solar cell module according to the third embodiment has the same structure as that of the solar cell module according to the first embodiment except that, with the third embodiment, the shielding member and the back face member are fused and bonded to each other, which is a feature of the third embodiment. FIG. 11 shows the principal components that relate to the feature of the third embodiment. It should be noted that the same components as in the first embodiment are denoted by the same reference numerals, and description thereof will be omitted as appropriate.

With a solar cell module 310 according to the third embodiment, the back face member 26 is formed of glass. With such an arrangement, the shielding member 44 is fused and bonded to the back face member 26 in at least a part of the perimeter of the through hole 38. More specifically, the shielding member 44 having a rectangular shape is fused and bonded to the back face member 26 in a bonding region R1 (hatched area in FIG. 11) in its outer edge region. It should be noted that, in such an outer edge region of the shielding member 44, the gap region 46 in which the lead wire 22b is interposed between the shielding member 44 and the back face member 26 is filled with a sealing member 42 formed of a butyl rubber or the like.

It should be noted that a raised portion 44c is provided along the outer edge of the side of the shielding member 44 that faces the back face member 26 so as to provide a space between the shielding member 44 and the back face member 26, giving consideration to the thickness of the lead wire 22b. The raised portion 44c may be monolithically formed by processing the shielding member 44. Also, the raised portion 44c may be formed by coating the outer edge of a flat glass plate with glass frit, and by firing the glass plate thus coated. Here, glass frit represents glass flake or powder obtained by melting a glass material at high temperature, and by rapidly cooling the melted glass material.

A notch 44d is formed in the raised portion 44c in order to allow the lead wire 22b to be drawn out to the exterior of the shielding member 44 without interference. It should be noted that the sealing member 42 preferably fills the interior space of the through hole 38, in addition to filling the gap region 46, as shown in FIGS. 12 and 13.

As described above, with the solar cell module 310, the shielding member 44 is fused and bonded to the back face member 26 in at least a part of the perimeter of the through hole 38 in a state in which it covers the through hole 38 formed in the back face member 26. Thus, such an arrangement provides high airtightness at least in a region where the shielding member 44 is fused and bonded to the back face member 26, which prevents moisture infiltration. Thus, such an arrangement suppresses the passage of external moisture through a gap between the shielding member 44 and the back face member 26. This suppresses moisture infiltration into the internal structure of the solar cell module 310 via the through hole 38. Thus, such an arrangement allows the solar cell module 310 to have improved reliability over a long period of time.

Here, “fused and bonded” can be regarded as a state in which a part of the shielding member 44 and a part of the back face member 26 are fused and are bonded to each other. More specifically, the “fused and bonded state” can be regarded as a state in which the material of the shielding member 44 and a glass material of the back face member 26 are fused and melded with each other at the interface between the shielding member 44 and the back face member 26.

### [Fusing and Bonding Method]

Next, description will be made regarding a method for fusing and bonding the shielding member 44 and the back face member 26.

In a step in which the shielding member 44 and the back face member 26 are fused and bonded to each other, first, the bonding region R1 in the outer edge region of the shielding member 44 is mounted in contact with the back face member 26 in a state in which the sealing member 42 is arranged so as to surround the lead wire 22b. Next, a laser apparatus focuses on the contact face of the bonding region R1 and irradiates it with a laser beam, and scans the laser beam along the four outer sides of the shielding member 44.

The laser beam is preferably configured as a femtosecond laser beam. That is to say, the laser beam is preferably configured to have a pulse width of 1 nsec or less. Furthermore, the laser beam is preferably configured to have a wavelength that yields absorption of the laser light by at least one of the shielding member 44 and the back face member 26. For example, the laser beam is preferably configured to have a wavelength of 800 nm. Moreover, the laser beam irradiation is preferably performed with a sufficient energy density and a suitable scanning speed for fusing the shielding member 44 and the back face member 26. For example, the laser beam irradiation is preferably performed with a wavelength of 800 nm, a pulse width of 150 fs, a pulse repetition rate of 1 kHz, and a pulse energy of 5 μJ per pulse. Furthermore, the laser beam is preferably scanned with a scanning speed of 60 mm/minute.

Using the same method, the translucent member 16 and the back face member 26 may be fused and bonded to each other along the outer edge portion without involving the sealing member 14. Also, the translucent member 16 and the back face member 26 may be fused and bonded to each other along the outer edge portion via a different member such as a glass member or the like.

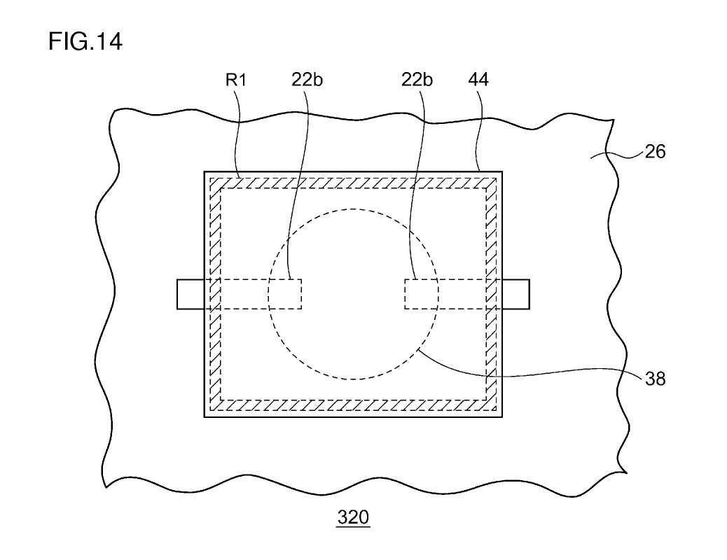

Also, the shielding member 44 may be fused and bonded to the back face member 26 along the entire perimeter of the through hole 38. FIG. 14 shows a modification of the solar cell module according to the third embodiment. With a solar cell module 320, a portion of the lead wire 22b to be interposed between the shielding member 44 and the back face member 26 is coated with glass frit, and a laser beam is scanned over the entire perimeter of the bonding region R1 for bonding the shielding member 44 and the back face member 26 in a state in which the lead wire 22b is interposed between the shielding member 44 and the back face member 26, thereby fusing and bonding the shielding member 44 and the back face member 26. Such an arrangement suppresses the passage of external moisture through a gap between the shielding member 44 and the back face member 26, thereby suppressing moisture infiltration into the internal structure of the solar cell module 320 via the through hole 38.

Description has been made above regarding the present invention with reference to the aforementioned embodiments. However, the present invention is by no means intended to be restricted to the aforementioned embodiments. Also, various modifications may be made by appropriately combining or replacing components of the aforementioned embodiments, which are also encompassed within the scope of the present invention. Also, various modifications may be made by modifying a combination of the embodiments, or otherwise modifying the order of the processing steps, or various designs may be modified, based on the knowledge of those skilled in this art, which are also encompassed within the scope of the present invention.

In addition to ethylene vinyl acetate (EVA), examples of the material that can be used to form the filler member 24 according to the aforementioned embodiments include: silicone; polyvinyl butyral (PVB); various kinds of polyolefin resin; ethylene resin such as ethylene ethyl acrylate copolymer resin (EEA), etc.; urethane resin; acrylic resin; epoxy resin; and the like. Also, in addition to butyl rubber, examples of the material that can be used to form the sealing members 14 and 42 according to the aforementioned embodiments include epoxy resin, polyolefin resin, and the like, each of which is a material having a low moisture vapor transmission rate.

Also, instead of the first electrode layer 30 formed of zinc oxide (ZnO), the first electrode layer 30 according to the respective embodiments may be configured as a layer formed of a single metal oxide selected from among tin oxide (SnO₂), indium oxide (In₂O₂), titanium oxide (TiO₂), zinc stannate (Zn₂SnO₄), and the like. Also, the first electrode layer 30 may be configured as a laminated layer body formed of multiple kinds of metal oxides selected from among the aforementioned metal oxides. It should be noted that such a metal oxide may be doped with fluorine (F), tin (Sn), aluminum (Al), gallium (Ga), niobium (Nb), or the like.

It should be noted the following combinations may be made with respect to the solar cell module, which are encompassed within the scope of the present invention.

(1) A solar cell module comprising:

a translucent member arranged on a light reception side;

a photovoltaic apparatus arranged on the translucent member;

a wire configured to allow electric energy generated by the photovoltaic apparatus to be output to the exterior;

a back face member having an opening configured to allow a part of the wire to pass through it, and arranged such that it faces the translucent member;

a shielding member arranged such that it overlays the opening on an outlet side of the opening, and configured to shield the opening; and

a sealing member configured to seal the opening,

wherein the wire is arranged so as to pass through a gap interposed between the shielding member and the back face member such that it bypasses the shielding member on the outlet side of the opening,

and wherein the sealing member is configured to seal the gap, in addition to sealing the opening.

Thus, assuming that the external moisture vapor cannot directly pass through the shielding member, the external moisture vapor must pass through the gap and bypass the shielding member before it reaches the opening. This lengthens the distance through the sealing member that the moisture vapor must pass through, as compared with an arrangement having no shielding member, thereby suppressing an amount of moisture vapor that can reach the photovoltaic apparatus via the sealing member. As a result, such an arrangement suppresses deterioration in the photovoltaic apparatus and the wiring member itself and suppresses degradation of the connection reliability of the respective connection portions that connect the respective components and wires, over a long period of time, thereby providing a solar cell module with a long service life.

(2) The solar cell module described in (1), wherein the shielding member is formed of glass.

Such an arrangement is capable of reducing an amount of moisture vapor that can directly pass through the shielding member.

(3) The solar cell module described in (2), wherein the back face member is formed of glass,

and wherein the shielding member is fused and bonded to the back face member in at least a part of a perimeter of the opening.

Such an arrangement suppresses the passage of external moisture through a gap between the shielding member and the back face member, thereby suppressing the infiltration of external moisture into the internal structure of the solar cell module via the opening.

(4) The solar cell module described in any one of (1) through (3), wherein the sealing member is formed of a butyl rubber.

Such an arrangement is capable of further reducing an amount of moisture vapor that can reach the internal structure of the solar cell module via the sealing member.

(5) The solar cell module described in (4), wherein, with the thickness of the back face member as t, and with the length of the gap region from an edge of the outlet side of the opening up to an edge of the shielding member as L, (t+L) is at least equal to 10 mm.

Such an arrangement provides a moisture vapor infiltration protection effect over a long period of time on the order of three times the test time (1000 hours) stipulated as the high-temperature and high-pressure test time (85° C., 85% RH).

(6) The solar cell module described in any one of (1) through (5), further comprising an output terminal connected to the wire,

wherein the shielding member is formed of an insulating material,

and wherein the wire is connected to the output terminal via solder on the shielding member.

This allows the wiring member and the output terminal to be connected to each other with the shielding member as a base.

(7) The solar cell module described in any one of (1) through (5), further comprising an output terminal connected to the wire,

wherein the wire is connected to the output terminal via solder with a gap between it and the shielding member.

Such an arrangement suppresses the transfer of heat to the sealing member and the photovoltaic apparatus via the shielding member when heat is generated in the step in which the wire is connected to the output terminal by means of soldering. Thus, such an arrangement suppresses alteration of the sealing member and degradation of the photovoltaic apparatus due to heat.

(8) The solar cell module described in any one of (1) through (7), further comprising:

a housing portion configured to house the shielding member; and

a filler member configured to fill an interior space of the housing portion,

wherein the filler member is formed of a material having a heat radiation performance that is higher than that of the sealing member.

Such an arrangement allows heat generated in the internal components and circuits such as the output terminal and the like arranged within the terminal box to be easily radiated to the exterior via the filler member.

What is claimed is:

1. A solar cell module comprising:
a translucent member arranged on a light reception side;
a photovoltaic apparatus arranged on the translucent member;
a wire configured to allow electric energy generated by the photovoltaic apparatus to be output to the exterior;
a back face member having an opening configured to allow a part of the wire to pass through it, and arranged such that it faces the translucent member;
a shielding member arranged such that it overlays the opening on an outlet side of the opening, and configured to shield the opening; and
a sealing member configured to seal the opening,
wherein the wire is arranged so as to pass through a gap interposed between the shielding member and the back face member such that it bypasses the shielding member on the outlet side of the opening,
and wherein the sealing member is configured to seal the gap, in addition to sealing the opening.

2. The solar cell module according to claim 1, wherein the shielding member is formed of glass.

3. The solar cell module according to claim 2, wherein the back face member is formed of glass,
and wherein the shielding member is fused and bonded to the back face member in at least a part of a perimeter of the opening.

4. The solar cell module according to claim 1, wherein the sealing member is formed of a butyl rubber.

5. The solar cell module according to claim 4, wherein, with the thickness of the back face member as t, and with the length of the gap region from an edge of the outlet side of the opening up to an edge of the shielding member as L, (t+L) is at least equal to 10 mm.

6. The solar cell module according to claim 1, further comprising an output terminal connected to the wire,
wherein the shielding member is formed of an insulating material,
and wherein the wire is connected to the output terminal via solder on the shielding member.

7. The solar cell module according to claim 1, further comprising an output terminal connected to the wire,
wherein the wire is connected to the output terminal via solder with a gap between it and the shielding member.

8. The solar cell module according to claim 1, further comprising:
a housing portion configured to house the shielding member; and
a filler member configured to fill an interior space of the housing portion,
wherein the filler member is formed of a material having a heat radiation performance that is higher than that of the sealing member.
